(19) United States
(12) Patent Application Publication
(10) Pub. No.: US 2020/0209059 A1
(43) Pub. Date: Jul. 2, 2020

(54) OPTOELECTRONIC DEVICE USING A PHASE CHANGE MATERIAL

(71) Applicant: Oxford University Innovation Limited, Oxford (GB)

(72) Inventors: Syed Ghazi SARWAT, Oxford (Oxfordshire) (GB); Gerardo Rodriguez HERNANDEZ, Oxford (Oxfordshire) (GB); Harish BHASKARAN, Oxford (Oxfordshire) (GB)

(21) Appl. No.: 16/611,938

(22) PCT Filed: May 3, 2018
(86) PCT No.: PCT/GB2018/051198

§ 371 Date: Nov. 8, 2019

(30) Foreign Application Priority Data
May 11, 2017 (GB) 1707594.6

(51) Int. Cl. G01J 1/44; H01L 45/00; H01L 31/09; H01L 31/0232; H01L 27/144

(52) U.S. Cl. CPC G01J 1/44; H01L 45/06; H01L 27/1446; H01L 31/02327; H01L 31/09

(57) ABSTRACT

An apparatus (200) for detecting light, comprising a detector (100) and a readout circuit (150). The detector (100) comprises: a substrate (10), a phase change material layer (16) supported by the substrate (10), a first electrode (14) in electrical contact with the phase change material layer (16), and a second electrode (18) in electrical contact with the phase change material layer (16). The first and second electrode (14, 18) are operable to bias the phase change material (16) by passing a current through the phase change material as a result of a bias voltage between the first and second electrode (14, 18). The readout circuit (15) is configured to: bias the phase change material layer (16) by applying a bias voltage between the first and second electrode (14, 18); detect light incident on the phase change material (16) by detecting a change in resistance of the phase change material layer (16) as a result of a phase change in the phase change material layer (16); reset the phase change material layer (16) after a phase change in the phase change material layer (16) by applying a reset pulse via the first and second electrode (14, 18).

### TECHNICAL FIELD

The invention relates generally to an optoelectronic device and method of operating the same. Particularly, but not exclusively, the invention relates to an optoelectronic device based on phase change materials and its use for photo-detection applications.

### BACKGROUND TO THE INVENTION

The development of inexpensive optical sensors with high photo-sensitivity and reduced size is driven by the positive impact they would have on a wide range of applications ranging from medical instrumentation to consumer electronics. Commercially available optical sensors that operate at room temperature in the visible to near infrared (IR) spectral range are typically based on semiconductor materials such as silicon (Si) and indium gallium arsenide (InGaAs). Image sensors that are typically used in cell phone cameras and web cameras today are based on Si active pixel sensor arrays manufactured using CMOS technology. Such sensors offer high photo-sensitivity but are expensive to manufacture, have a limited dynamic range and are not easily scaled down in size. In most conventional semiconductor-based optical sensors responsive to visible light near-IR light, the photo-response originates from the separation and drift of photo-excited charge carriers (photocarriers) in an electric field present between the terminals of the device. The electric field is either: an internal/built-in electric field, such as that present at a p-n junction; an external electric field, such as that generated by an applied bias; or a combination of both. As such, for a given incident optical power the photo-response is largely determined by material specific properties that govern photocarrier generation and drift, such as optical absorption and charge carrier mobility. These properties are fixed. The dynamic range, i.e. the useful range of optical power over which the device can operate, is also limited by material specific properties, meaning that typical optical devices saturate at fixed and relatively low light levels. By contrast, the human eye has a wide dynamic range because it can adapt to varying levels of light intensity via the contractual structure around the pupil.

Alternative optoelectronic devices and methods of photodetection are desirable, preferably with increased adaptability to light levels.

### SUMMARY OF THE INVENTION

According to a first aspect, there is provided an apparatus for detecting light, comprising a detector and a readout circuit. The detector comprises: a substrate, a phase change material layer supported by the substrate, a first electrode in electrical contact with the phase change material layer, and a second electrode in electrical contact with the phase change material layer. The first and second electrode are operable to bias the phase change material by passing a current through the phase change material as a result of a bias voltage between the first and second electrode. The readout circuit is configured to:
bias the phase change material layer by applying a bias voltage between the first and second electrode;
detect light incident on the phase change material by detecting a change in resistance of the phase change material layer as a result of a phase change in the phase change material layer; and
reset the phase change material layer after a phase change in the phase change material layer by applying a reset pulse via the first and second electrode.

The term “light” is used in this specification in a non-restrictive sense, to refer generally to any form of electromagnetic radiation. Some embodiments may be suitable for detecting light with wavelengths in the range 10 nm to 1 mm, or 400 nm to 700 nm.

Detecting a change in resistance may comprise detecting a change in the current flowing through the phase change material as a result of the bias voltage.

The first and second electrode may be respectively disposed below and above the phase change material layer. The first electrode may be in electrical contact with a lower surface of the phase change material layer, and the second electrode may be in electrical contact with an upper surface of the phase change material layer.

The detector may comprise a mirror layer, arranged to reflect light through the phase change material layer so as to increase the absorbance of incident light by the detector.

The detector may be configured to act as a resonant optical cavity so as to maximise the absorbance of a selected wavelength of light by the detector.

The selected wavelength may be within the range 400 nm to 700 nm.

The first and second electrode may comprise an at least partially transparent conducting material.

The first and second electrode may comprise indium tin oxide, graphene, multi-layer graphene, graphite, gold, or PEDOT.

The phase change material may comprise a compound or alloy of a combination of elements selected from the following list of combinations: GeSbTe, VOx, NbOx, GeTe, GeSb, GaSb, AgInSbTe, InSb, InSbTe, InSe, SbTe, TeGeSbS, AgSbSe, SbSe, GeSbMnSn, AgSbTe, AuSbTe, and AlSb.

The readout circuit may be operable in a count rate mode, in which a light flux on the detector is inferred from the rate at which the readout circuit resets the detector.

The readout circuit may be operable in a sub-threshold mode, in which a light flux on the detector is inferred from a resistance of the phase change material in the amorphous state.

The readout circuit may be configured to adjust the bias voltage to vary the sensitivity and/or dynamic range of the detector.

The readout circuit may be configured to adjust the bias voltage to vary the sensitivity of the device in response to a count rate of resets of the detector.

The readout circuit may be configured to adjust the bias voltage to vary the dynamic range of the detector in response to a reset event, so as to vary the amount of light incident on the detector required to cause a phase transition in the phase change material layer.

The detector may comprise a plurality of pixels, each pixel comprising:
a phase change material layer, a first electrode in electrical contact with the phase change material layer, and a second electrode in electrical contact with the phase change material layer, wherein, for each pixel, the first and second electrode are operable to bias the phase change material by passing a current through the phase change material as a result of a bias voltage between the first and second electrode, so that each pixel independently responds to light; and
wherein the readout circuit is configured to, for each pixel:
   bias the phase change material layer by applying a bias voltage between the first and second electrode;
   detect light incident on the phase change material by detecting a change in resistance of the phase change material layer as a result of a phase change in the phase change material layer;
   reset the phase change material layer after a phase change in the phase change material layer by applying a reset pulse via the first and second electrode bias.

According to a second aspect, there is provided a method of detecting radiation incident on a detector, the detector comprising: a phase change material layer, a first electrode in electrical contact with the phase change material layer, and a second electrode in electrical contact with the phase change material layer, the method comprising:
biasing the phase change material layer by applying a bias voltage between the first and second electrode;
detecting light incident on the phase change material by detecting a change in resistance of the phase change material layer as a result of a phase change in the phase change material layer;
resetting the phase change material layer after a phase change in the phase change material layer by applying a reset pulse via the first and second electrode.

The method may be performed using an apparatus according to the first aspect, including any of the optional features thereof, in any combination.

More generally, features which are described in the context of separate aspects and embodiments of the invention may be used together and/or be interchangeable. Similarly, where features are, for brevity, described in the context of a single embodiment, these may also be provided separately or in any suitable sub-combination. Features described in connection with the device may have corresponding features definable with respect to the method(s) and these embodiments are specifically envisaged.

### BRIEF DESCRIPTION OF DRAWINGS

In order that the invention can be well understood, embodiments will be discussed below by way of example only with reference to the accompanying drawings, in which:

FIG. 1 is a schematic top view of a thin film device and a cross-section of the layer structure;

FIG. 2 is a schematic diagram of an apparatus according to an embodiment;

FIG. 3 is a graph showing current-voltage characteristics for a detector for use in an embodiment in an amorphous state, measured in the dark;

FIG. 4 is a graph showing current as a function of incident optical power (at 632 nm) when the PCM is in an amorphous state;

FIG. 5 is a graph showing current as a function of incident optical power (at 632 nm) when the PCM is in a crystalline state;

FIG. 6 is a graph showing a current-voltage sweep for a detector, measured under a constant optical excitation at 532 nm with a power density of 1592 mW/cm², showing switching to the crystalline state;

FIG. 7 is a flow diagram illustrating a method according to an embodiment;

FIG. 8 is a graph showing repeated cycles of phase change performed on a phase change material; and

FIG. 9 is a schematic of an apparatus according to an embodiment under test with a laser light source.

### DETAILED DESCRIPTION

Phase-change materials (PCMs), have been the subject of intense research and development over the last decade, for example in the context of electronic memories. PCMs may exhibit a high contrast in their electrical and optical properties between a crystalline and an amorphous phase. In particular, PCMs (e.g. chalcogenide-based PCMs, such as GST) may have the ability to switch between these two states in response to appropriate heat stimuli (resulting in crystallization) or melt-quenching processes (resulting in amorphization). The phase transition occurs at a crystallisation temperature, Tc. Initially, at temperatures below T_{C} the PCM may be in the amorphous state. When heated to temperatures above T_{C} the PCM transitions to the crystalline state, and remains in the crystalline state when it is cooled back to below T_{C}. The PCM can be “reset” back to the amorphous state by heating it above the melting point, T_{M}, and rapidly cooling it back to below T_{C}.

These PCMs (which include tellurides and antimonides) can be switched on a sub-nanosecond timescale with high reproducibility, which enables ultra-fast operation over switching cycles up to 10¹² times using current-generation materials. New and improved PCM materials, such as the so-called phase-change super-lattice materials, are expected to deliver even better performance in the future.

In addition to a change in electrical conductivity, many PCMs show significant change in refractive index (optical reflectance/transmission) in the visible and even larger changes in the near-infrared wavelength regime. In particular, the amorphous state may have a low electrical conductivity and low reflectance, and the crystalline state may have a relatively high conductivity and high reflectance.

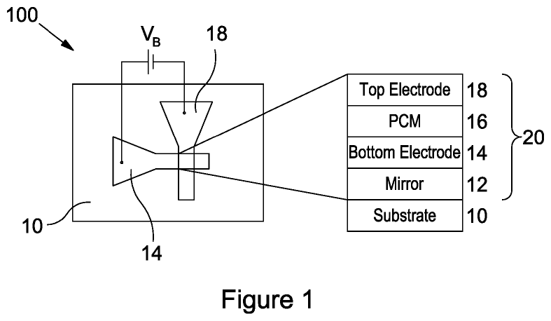

FIG. 1 shows a detector 100 suitable for use in an embodiment of the invention. The detector 100 comprises a layer stack 20 deposited onto a substrate 10. The layer stack 20 comprises a plurality of layers stacked on top of one another. Each layer may comprise a different material, or two or more layers may comprise substantially the same material. The layer stack 20 comprises a layer of PCM 16 sandwiched between a first electrode 14 and a second electrode 18. The layer stack 20 may further comprise a mirror layer 12. The mirror layer 12 may be positioned between the first electrode 12 and the substrate 10.

Although this device employs a vertical structure, in which the first electrode 14 is a lower electrode, and the second electrode 14 is an upper electrode, and the PCM layer is sandwiched between the lower 14 and upper 18 electrode, other embodiments may employ a lateral structure, comprising electrodes configured to pass current through the PCM layer laterally. Such lateral electrodes may be patterned from a single layer, and/or may be in electrical contact with only one side of the PCM layer. In other embodiments lateral electrodes may be in contact with both sides of the PCM layer.

The detector may comprise a further encapsulation layer (not shown), which may comprise an oxide or polymer, for example, to protect the layer stack 20 from degradation.

It will be understood that use of terms such as “upper” and “lower” do not limit the orientation of the detector 100 in use, and are used in a relative sense.

The substrate 10 may be substantially opaque and absorbing in the visible spectrum. Alternatively, substrate 10 may be substantially optically transparent in the visible spectrum. Where the substrate 10 is substantially transparent in the visible spectrum, the mirror layer 12 may be positioned to allow the PCM layer 16 to be illuminated from the back side (through the substrate 10). For instance, in the case of a vertical device, the mirror layer 12 may be positioned above the upper electrode 18.

In the exemplary embodiments described below, the PCM 16 is the well-studied germanium antimony tellurite (GST) compound or alloy, Ge₂Sb₂Te₅, because of its proven chemical and solid state stability down to nanoscale dimensions and potential for device miniaturisation. GST has T_{C}˜150 degrees C. and T_{M}˜600 degrees C.

In other embodiments, the PCM 16 may be or comprise material comprising a compound or alloy of a combination of elements selected from the following list of combinations: GeSbTe, VOx, NbOx, GeTe, GeSb, GaSb, AgInSbTe, InSb, InSbTe, InSe, SbTe, TeGeSbS, AgSbSe, SbSe, GeSbMnSn, AgSbTe, AuSbTe, and AlSb. The PCM may be doped with any element (e.g. C, Ni, Ce, Si etc).

The PCM layer 16 may have a thickness in the range 10 nm to 50 nm. In other embodiments, the PCM layer 16 may have a thickness in the range 10 nm to 20 nm, 20 nm to 30 nm, 30 nm to 40 nm, or 40 nm to 50 nm.

The PCM layer 16 may have a switching time of less than 1 microsecond, or preferably less than 1 nanosecond. The PCM layer 16 may have a T_{C} less than 200 degrees C. and preferably less than 150 degrees C. The PCM layer 16 may have a high phase stability characterised by large difference in T_{M} and T_{C}. The PCM layer 16 may have a T_{M}-T_{C} value in the range of 100 to 200 degrees C., 200 to 300 degrees C., 300 to 400 degrees C., or 400 to 500 degrees C., or a T_{M}-T_{C} value greater than 500 degree C.

The upper electrode 18 and the lower electrode 14 comprise an electrically conductive material. In an embodiment, the electrodes 14, 18 may have an electrical conductivity greater than 1×10³ S/cm. In other embodiments, the electrodes 14, 18 may have an electrical conductivity greater than 1×10² S/cm or 10 S/cm.

The upper and/or lower electrodes 14, 18 are at least partially transparent in the visible spectrum. In an embodiment, the upper and lower electrodes 14, 18 have a transmission of at least 50% in the visible spectrum (e.g. 400 nm to 700 nm), or an average transmission of at least 50%. In other embodiments, the electrodes 14, 18 have a minimum transmission of at least 60%, 70%, 80% or 90%.

The upper and/or lower electrode 14, 18 may be or comprise a metal, metal alloy, semi-metal, semi-metal alloy, semiconductor, semiconductor compound, oxide or polymer. Suitable materials for the upper and lower electrode 14, 18 may include, but are not limited to: indium tin oxide (ITO), graphene, multi-layer graphene, graphite, gold, PEDOT (poly(3,4-ethylenedioxythiophene) polystyrene sulfonate).

The upper and lower electrode 14, 18 may not comprise the same material or the same electrical/optical properties.

In the exemplary embodiments described below, ITO is used due to its ease of fabrication and well controlled optical and electronic properties.

The upper and/or lower electrode 14, 18 may have a thickness in the range 10 nm to 50 nm. The thickness of the upper electrode 18 and lower electrode 14 may not be equal. In other embodiments, the upper and/or lower electrodes 14, 18 may have a thickness in the range 10 nm to 20 nm, 20 nm to 30 nm, 30 nm to 40 nm, or 40 nm to 50 nm.

The mirror layer 12 may have a reflectivity greater than 90% in the visible spectrum. In another embodiment, the mirror layer may have a reflectivity greater than 85%, 80% or 75% in the visible spectrum. The mirror layer may be or comprise a material which does not absorb light in the wavelength range of interest. In an embodiment, the mirror layer may be or comprise a metal layer. For example, the mirror layer 12 may be or comprise aluminium.

The layer stack 20 of the detector 100 comprises a number of partially transparent thin films (14, 16, 18) stacked on top of each other and a substrate 10. The layer stack may or may not include a mirror layer 12. The layer stack 20 may be designed to provide a maximum (enhanced) optical absorption in the PCM layer 16 for specific wavelengths in the visible spectrum, while a minimum optical absorption in the PCM layer 16 for the rest of the visible spectrum. This can be achieved by exploiting thin film interference effects which can be modelled using well known techniques, for example using commercially available software such as COMSOL Multiphysics. The detector 100 may therefore be configured to be wavelength selective, such that it operates at certain wavelengths only. In the detector 100 for which results are shown herein, 40-55% absorption at a wavelength of 632 nm is achieved for a 15 nm thick GST layer 16, where the layer stack 20 has a 20 nm thick ITO layer 18, a 15 nm thick GST layer 16 and a 20 nm thick ITO layer 14 on top of a 300 nm/10 μm thick SiO2/Si substrate 10. Since the photoresponse is proportional to the optical absorption, the layer stack 20 may provide both wavelength selectivity and enhanced photoresponse at that wavelength.

The detector 100 may be fabricated using a number of processing steps known in the art. The PCM layer 16 and/or electrodes 14, 18 may be deposited with any appropriate technique, for instance using physical or chemical methods, such as thermal evaporation, electron beam evaporation, sputtering, chemical vapour deposition, atomic layer deposition, etc., depending on the materials required. In the following example embodiments, RF sputtering was used for deposition of the PCM layer 16 and the electrodes 14, 18.

The detector may be fabricated using a “bottom up” approach, where the PCM layer 16 and/or electrodes 14, 18 are defined by a deposition and lift-off process. Alternatively, the detector 100 may be fabricated using a “top-down” approach, where the PCM layer 16 and/or electrodes 14, 18 are defined by a deposition and subtractive etch process. The detector fabrication may involve a combination of lift-off and etch processes. The detector fabrication may involve optical lithography and/or electron beam lithography steps. The features and steps of the fabrication process are merely exemplary, and embodiments may be fabricated in other ways.

The upper electrode 18 and lower electrode 14 provide an electrical contact to an upper and lower side of the PCM layer 16, respectively. In an embodiment, the upper and lower electrodes may provide an Ohmic contact to the PCM layer 16 with a low contact resistance. In an embodiment, the contact resistance may be less than 1×10⁻³ Ωcm². In other embodiments, the contact resistance may be less than 1×10⁻⁴ Ωcm², 1×10⁻⁵ Ωcm², 1×10⁻⁶ Ωcm², 1×10⁻⁷ Ωcm² or 1×10⁻⁸ Ωcm².

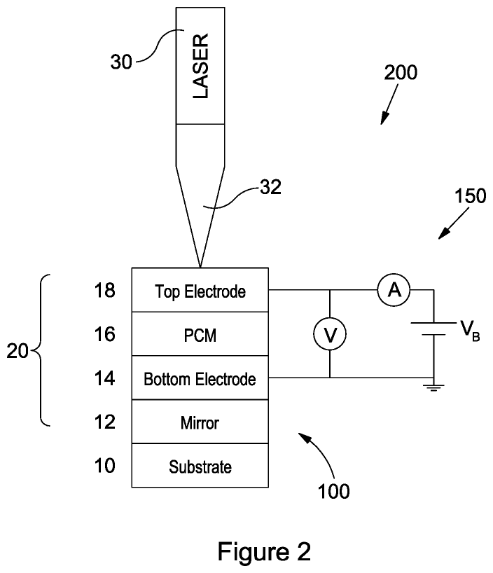

The upper and lower electrode 14, 18 are further configured to connect to a readout circuit 150, as explained more fully with reference to FIG. 2.

FIG. 2 illustrates an apparatus 200 for detecting light in accordance with an embodiment, comprising a detector 100 and a readout circuit 150.

The detector 100 is as described with reference to FIG. 1. The readout circuit 150 comprises a voltage source, which is schematically illustrated as a cell. The voltage source may be a programmable voltage source, or an additional control element may be provided, operable to vary the bias voltage V_{B} applied to the PCM layer 16 via the first and second electrode 14, 18. The voltage source is electrically connected to the first and second electrode 14, 18. The readout circuit 150 further comprises a current detector A, for monitoring the amount of current flowing through the PCM layer 16 as a result of the applied bias voltage. A voltage detector V may also be provided for monitoring the bias voltage.

The voltage source may comprise a low noise DC source, such as a battery. Alternatively, the voltage may be derived from an AC source. The current may be monitored by any suitable means, such as using a current pre-amplifier or measuring the voltage across a series resistor of known resistance. Where an AC source is used, the AC current or voltage may be measured using known phase sensitive detection techniques, such a lock-in amplifier.

The detector 100 can be exposed to an optical flux 32 from optical source 30. In the example shown in FIG. 2, the optical source 30 is a laser. However, the source 30 may be any optical source.

When the detector 100 is exposed to an optical flux 32, incident light is absorbed in the PCM layer 16. The generation of photocarriers may increase the electrical conductivity of the PCM layer 16, and/or may simply heat the PCM layer 16. When a constant bias voltage is applied to the PCM layer 16, the change in electrical conductivity due to incident light flux will result in an increase in current through the PCM layer 16.

In a first readout modality (a count rate mode), the readout circuit 150 is configured to apply a relatively high bias voltage to the PCM layer 16, which is initially in an amorphous state, so that a relatively small amount of incident light on the PCM layer 16 will result in an increase in temperature beyond Tc, resulting in a phase change of the PCM layer 16 to a crystalline state. With a sufficiently high bias voltage, the detector 100 can be made very sensitive to incident light. A lower bias voltage will mean that each reset event corresponds to a higher light flux. The phase change will result in a reduction in resistivity of the PCM layer 16, resulting in an increase in current flow, which the readout circuit is configured to detect. The readout circuit 150 subsequently resets the detector 100 by amorphizing the PCM layer 16, which may happen very quickly (e.g. in less than: 1 ms, 100 μs, 10 μs, or 1 μs). The detector 100 is then ready to be crystallized by another incident pulse of light.

The rate of reset events is a measure of the intensity of the light 32 incident on the detector 100. Because the sensitivity of the detector 100 depends on the applied bias voltage V_{B}, the sensitivity of the detector 100 may be dynamically adjusted, for instance in response to the rate of reset events. The readout circuit 150 may be configured to vary the bias voltage according to a predefined relationship with the count rate (for example, defined in a mathematical expression or a look-up table). A higher rate of reset events may result in a reduced bias voltage, and a lower rate of reset events may results in an increased bias voltage.

In a second readout modality (a sub-threshold mode), the readout circuit 150 may be configured to detect light incident on detector based on the change in resistance of the PCM layer prior to a phase transition. In this sub-threshold readout mode a reset of the detector may occur when an unusually high rate of light flux is incident on the device.

The PCM layer 16 may have different optical properties in the crystalline state (compared with in the amorphous state), which may result in a change in the wavelength absorbed by the detector 100 following a phase change.

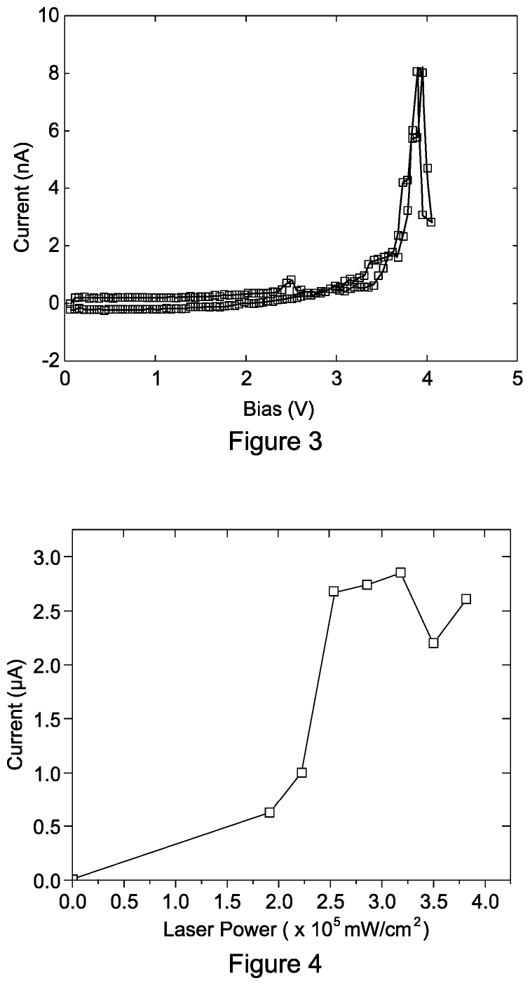

The current-voltage (or IV) characteristics of PCMs (in both the amorphous and crystalline states) can be typically segmented into two portions owing to a threshold switching mechanism (Poole-Frenkel effect): It is Ohmic at low bias voltages and non-linear at high biases. FIG. 3 shows the DC IV characteristics for the detector 100 in the amorphous state, measured in the dark. In the amorphous state the detector 100 is typically characterised by having a high resistance (R) on the order of tens of MOhm. By contrast, in the crystalline state the detector 100 is characterised by having a relatively low resistance on the order of hundreds of kOhm (not shown).

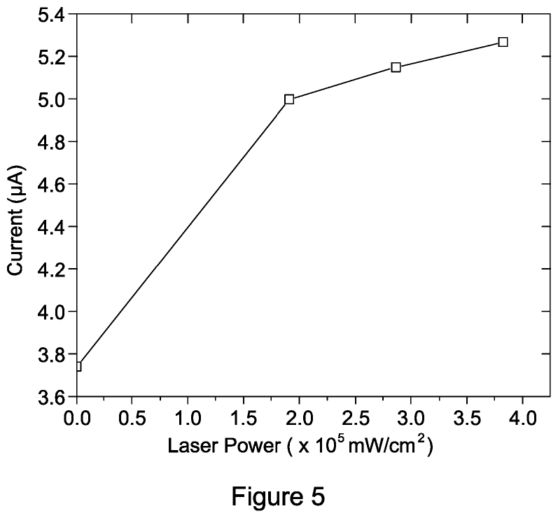

FIGS. 4 and 5 show the measured current in the detector 100 at a bias voltage of 1.4 V as a function of the incident optical power at 632 nm, when in the amorphous and crystalline state, respectively. The layer stack 20 was designed to provide 40% absorption in the PCM layer 16 at 632 nm. The data shows the general trend of increasing current with optical flux. The change in resistance with increasing optical flux may be attributed to a negative temperature coefficient of resistivity of the PCM layer and/or a photoconductive response of the PCM layer. The current at zero incident power is greater in the crystalline state due to the increased conductivity.

Aside from changing the temperature of the ambient environment, the temperature of the PCM layer 16 may be altered by electrical and optical mechanisms.

When the detector 100 is electrically biased, power dissipation in the detector (proportional to I²R) increases the temperature of the layers of the detector 100 through Joule heating. Due to the relatively high resistance of the PCM layer 16 compared to the electrodes 14, 18, most of the power is dissipated in the PCM layer 16. As such, the PCM layer 16 is heated up more than the electrode layers 14, 18.

In addition, optical excitation of the detector 100 with light in the visible spectrum generates photocarriers in the PCM layer 16 with initially high energies. The photocarriers undergo rapid energy relaxation via interactions with phonons, which transfers energy to the lattice and increases the temperature of the PCM layer 16.

Either of these mechanisms may be sufficient to switch the detector 100 from amorphous to crystalline state. The detector 100 according to the present invention may operate using of both these mechanisms.

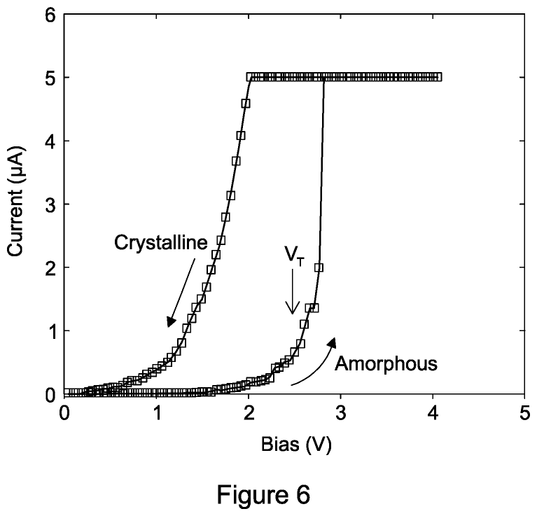

FIG. 6 shows a current-voltage sweep for a detector 100 measured under a constant optical excitation at 532 nm with a power density of 1592 mW/cm². Prior to the measurement, the PCM is in the amorphous state. Voltage is swept from 0 V to 4 V and back to 0V. The apparent truncation at 5 μA due to a compliance limit of the current measurement apparatus being reached (the current is limited to a maximum of 5 μA). The detector 100 exhibits a clear switching event from the amorphous state to the crystalline state, evidenced by the hysteretic behaviour. As shown in FIGS. 3 and 4, neither optical excitation at 1592 mW/cm², nor a voltage bias up to 4V, are sufficient alone to induce a phase change. This demonstrates the combined action of the light and the electrical current in switching the PCM 16. Providing a bias voltage of near to 4V would mean that a relatively small incident light flux will result in phase change of the PCM.

As shown in FIG. 6, when illuminated in the amorphous state, the detector 100 exhibits a strong non-linearity around a switching (threshold) voltage, V_{T}, beyond which the detector 100 switches from the amorphous state to the crystalline state. After exceeding V_{T}, when the voltage is then reduced, the detector 100 remains in the crystalline state.

In use, the detector 100 may be biased to a voltage just below or at the non-linear switching region of V_{T}. Optical excitation at or near the wavelength for which the layer stack 20 has been optimised increases the current flowing through the detector 100 (by the effect of a negative TCR in combination with an increase in temperature due to light absorption, and/or by a photoconductive effect). This induces a phase switching event in the PCM 16 manifested by a jump in the measured current or conductance spike. Optical excitation increases the current flow, which in turn induces a phase change in the PCM 16 which further increases the current. The change in current resulting from the phase change may be greater than the TCR/photoconductive response in the amorphous state alone.

The amount of light, or the optical flux, required to induce the switching event can be controlled by adjusting the value of the applied bias voltage, V_{B}. The further away the bias voltage is from (below) V_{T}, the more optical flux is required to switch the detector 100. Conversely, for more sensitivity, an electrical bias close to V_{T} can be applied. In this way, the sensitivity of the detector 100, or the range of optical power that can be sensed by the detector 100, may be regulated/controlled.

The conductance spike or rapid increase in current that occurs when the PCM 16 switches from amorphous to crystalline may be used as a trigger signal in a feedback circuit. The feedback circuit may function as an automatic brightness adjuster.

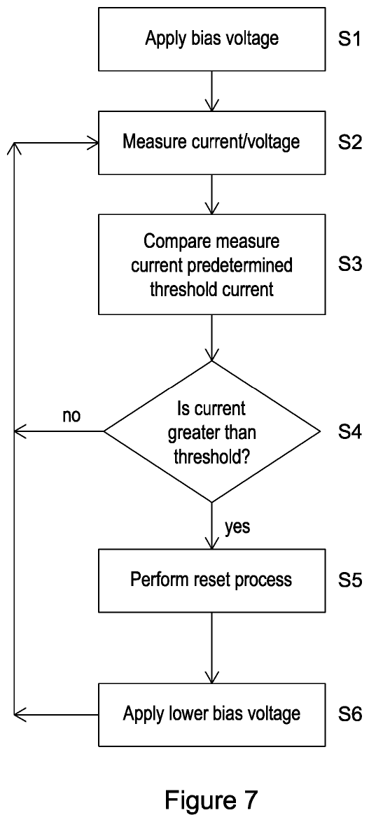

A method of operating the detector 100 is shown in FIG. 7. At step S1 a bias is applied to the detector. At step S2 the current and/or voltage is measured. The measured current value is compared to a predetermined threshold value at step S3. When the measured current value is less than the threshold value, at step S4 the process loops back to step S2. When the measured current exceeds the threshold value, at step S4 a “reset” process (step S5) may be initiated, to transition the PCM 16 back to the amorphous state. After the reset, at step S6, the bias voltage may be varied to adjust the optical power required to induce switching or reach the threshold current, for example based on a detected count rate of resets (as already discussed above). The current is then measured again at step S2 and the process continues. In this way, the detector 100 may continue to function in capture information on the intensity of the incident light while in the amorphous state.

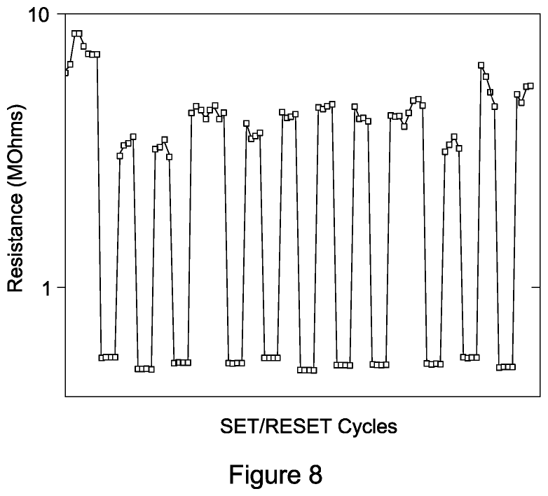

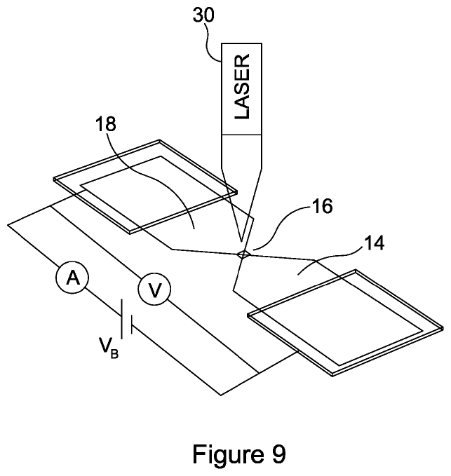

The reset process may be electrically driven. For example, a sufficiently large current may applied to the detector 100 for a short period of time to heat the PCM 16 above T_{M} and allow the material to cool back down in the amorphous state. FIG. 8 shows a number of “reset” cycles performed over time where the detector 100 has been electrically driven between the amorphous (high resistance) and crystalline (low resistance) state. The reset cycling may be advantageous/necessary to condition and/or stabilise the detector before optical measurements commence.

The vertical stack arrangement of the detector 100 may reduce a transit length of photocarriers through the PCM 16 and may also reduce the transit time of photocarriers, i.e. the time taken for photocarriers (travelling at the drift velocity) to traverse the PCM 16. This may enhance photoresponse by providing optical gain, whereby a photocarrier can traverse the detector 100 many times before it recombines.

It will be understood that because a layer stack 20 is designed to absorb a specific wavelength or wavelength range of interest in the visible spectra, the detector will not operate as intended for wavelengths outside of the specified range. In other words, the layer stack 20 functions as a colour filter. For example, if a detector 100 is designed to detect red light, it will not detect green light or blue light. The wavelength selectively and scalability of the detectors 100 means that they are well suited for application in image sensor arrays to capture 2D images with colour information. The controllable dynamic gain may be particularly suited to applications with varying light levels. Applications may include an artificial retina.

Image sensors commonly use a colour filter array over the pixel sensor array to filter the wavelength of light detected by the pixel sensors. A common example is a Bayer filter which gives information about the intensity of red, green and blue (RGB) wavelengths. The RGB data can be converted to full colour images with appropriate demosaicing algorithms. Since the detectors 100 may comprise a colour filter, arrays of detectors 100 designed for each specific colour may be used without a colour filter array.

An apparatus 200 has been described that operates in a mixed mode optoelectronic configuration. The apparatus 200 operates with in an inherent negative feedback loop, where the electrical conductance of the detector is modulated by the optical input flux and the output current signal is used as a trigger to self-modulate. This essentially replicates functioning of a human eye, where the amount of light striking the retina is controlled by the contractile structure around the pupil. The detectors 100 are extremely fast, robust, sensitive and wavelength selective. Further, the detectors 100 can be readily scaled down in size, enabling very high detector densities, and thereby high spatial image resolution. Furthermore, unlike commonly used charge-coupled devices (CCD) and complementary metal oxide semiconductor (CMOS) CCD image sensors, the detectors 100 are energy inexpensive, relatively simple in their construction and operation and inexpensive to fabricate.

From reading the present disclosure, other variations and modifications will be apparent to the skilled person. Such variations and modifications may involve equivalent and other features which are already known in the art, and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination.

For the sake of completeness it is also stated that the term “comprising” does not exclude other elements or steps, the term “a” or “an” does not exclude a plurality, and any reference signs in the claims shall not be construed as limiting the scope of the claims.

1. An apparatus for detecting light, comprising a detector and a readout circuit, wherein the detector comprises:
a substrate, a phase change material layer supported by the substrate, a first electrode in electrical contact with the phase change material layer, and a second electrode in electrical contact with the phase change material layer, wherein the first and second electrode are operable to bias the phase change material by passing a current through the phase change material as a result of a bias voltage between the first and second electrode;
and the readout circuit is configured to:
bias the phase change material layer by applying a bias voltage between the first and second electrode;
detect light incident on the phase change material by detecting a change in resistance of the phase change material layer as a result of a phase change in the phase change material layer;
reset the phase change material layer after a phase change in the phase change material layer by applying a reset pulse via the first and second electrode.

2. The apparatus of claim 1, wherein the first and second electrode are respectively disposed below and above the phase change material layer, the first electrode in electrical contact with a lower surface of the phase change material layer, and the second electrode in electrical contact with an upper surface of the phase change material layer.

3. The apparatus of claim 2, wherein the detector comprises a mirror layer, arranged to reflect light through the phase change material layer so as to increase the absorbance of incident light by the detector.

4. The apparatus of any preceding claim, wherein the detector is configured to act as a resonant optical cavity so as to maximise the absorbance of a selected wavelength of light by the detector.

5. The apparatus of claim 4, wherein the selected wavelength is within the range 400 nm to 700 nm.

6. The apparatus of any preceding claim, wherein the first and second electrode comprise an at least partially transparent conducting material.

7. The apparatus of claim 6, wherein the first and second electrode comprises indium tin oxide, graphene, multi-layer graphene, graphite, gold, or PEDOT.

8. The apparatus of any preceding claim, wherein the phase change material comprises a compound or alloy of a combination of elements selected from the following list of combinations: GeSbTe, VOx, NbOx, GeTe, GeSb, GaSb, AgInSbTe, InSb, InSbTe, InSe, SbTe, TeGeSbS, AgSbSe, SbSe, GeSbMnSn, AgSbTe, AuSbTe, and AlSb.

9. The apparatus of any preceding claim, wherein the readout circuit is operable in a count rate mode, in which a light flux on the detector is inferred from the rate at which the readout circuit resets the detector.

10. The apparatus of any preceding claim, wherein readout circuit is operable in a sub-threshold mode, in which a light flux on the detector is inferred from a resistance of the phase change material in the amorphous state.

11. The apparatus of any preceding claim, wherein the readout circuit is configured to adjust the bias voltage to vary the sensitivity and/or dynamic range of the detector.

12. The apparatus of claim 9, wherein the readout circuit is configured to adjust the bias voltage to vary the sensitivity of the device in response to a count rate of resets of the detector.

13. The apparatus of claim 10, wherein the readout circuit is configured to adjust the bias voltage to vary the dynamic range of the detector in response to a reset event, so as to vary the amount of light incident on the detector required to cause a phase transition in the phase change material layer.

14. The apparatus of any preceding claim, wherein the detector comprises a plurality of pixels, each pixel comprising:
a phase change material layer, a first electrode in electrical contact with the phase change material layer, and a second electrode in electrical contact with the phase change material layer, wherein, for each pixel, the first and second electrode are operable to bias the phase change material by passing a current through the phase change material as a result of a bias voltage between the first and second electrode, so that each pixel independently responds to light; and
wherein the readout circuit is configured to, for each pixel:
bias the phase change material layer by applying a bias voltage between the first and second electrode;
detect light incident on the phase change material by detecting a change in resistance of the phase change material layer as a result of a phase change in the phase change material layer;
reset the phase change material layer after a phase change in the phase change material layer by applying a reset pulse via the first and second electrode bias.

15. A method of detecting radiation incident on a detector, the detector comprising: a phase change material layer, a first electrode in electrical contact with the phase change material layer, and a second electrode in electrical contact with the phase change material layer, the method comprising:
biasing the phase change material layer by applying a bias voltage between the first and second electrode;
detecting light incident on the phase change material by detecting a change in resistance of the phase change material layer as a result of a phase change in the phase change material layer;
resetting the phase change material layer after a phase change in the phase change material layer by applying a reset pulse via the first and second electrode.

16. The method of claim 15, comprising using an apparatus in accordance with any of claims 1 to 14.
